(19) United States
(12) Patent Application Publication
(10) Pub. No.: US 2023/0261441 A1
(43) Pub. Date: Aug. 17, 2023

(54) EMITTER WITH AN OXIDE-LAYER-BASED REFLECTOR PAIR

(71) Applicant: Lumentum Operations LLC, San Jose, CA (US)

(72) Inventors: Yeyu ZHU, San Jose, CA (US); Chien-Yao LU, San Jose, CA (US)

(21) Appl. No.: 17/656,303

(22) Filed: Mar. 24, 2022

Related U.S. Application Data
(60) Provisional application No. 63/267,852, filed on Feb. 11, 2022.

(51) Int. Cl. H01S 5/183; H01S 5/20

(52) U.S. Cl. CPC H01S 5/18311; H01S 5/18377; H01S 5/18394; H01S 5/2086

(57) ABSTRACT

In some implementations, a vertical cavity surface emitting laser (VCSEL) device may include a substrate layer and a set of epitaxial layers disposed on the substrate layer. The set of epitaxial layers may include a first mirror and a second mirror. At least one of the first mirror or the second mirror may include at least one reflector pair that includes a semiconductor material layer and an oxidized semiconductor material layer. The set of epitaxial layers may include an oxidation trench axially extending into at least the second mirror, an active region between the first mirror and the second mirror, and an oxidation layer with an oxidation aperture.

### CROSS-REFERENCE TO RELATED APPLICATION

This Patent Application claims priority to U.S. Provisional Patent Application No. 63/267,852, filed on Feb. 11, 2022, and entitled “RING-SHAPED VERTICAL CAVITY SURFACE EMITTING LASERS.” The disclosure of the prior Application is considered part of and is incorporated by reference into this Patent Application.

### TECHNICAL FIELD

The present disclosure relates generally to vertical cavity surface emitting lasers (VCSELs) and to an emitter with an oxide-layer-based reflector pair.

### BACKGROUND

A vertical-emitting device, such as a VCSEL, may include a laser, an optical transmitter, or the like, in which a beam is emitted in a direction perpendicular to a surface of a substrate (e.g., vertically from a surface of a semiconductor wafer). Multiple vertical-emitting devices may be arranged in one or more emitter arrays (e.g., VCSEL arrays) on a common substrate.

### SUMMARY

In some implementations, a VCSEL device may include a substrate layer and a set of epitaxial layers disposed on the substrate layer. The set of epitaxial layers may include a first mirror and a second mirror. At least one of the first mirror or the second mirror may include at least one reflector pair that includes a semiconductor material layer and an oxidized semiconductor material layer. The set of epitaxial layers may include an oxidation trench axially extending into at least the second mirror, an active region between the first mirror and the second mirror, and an oxidation layer with an oxidation aperture.

In some implementations, an emitter device may include a substrate layer and a set of epitaxial layers disposed on the substrate layer. The set of epitaxial layers may include a first mirror and a second mirror. At least one of the first mirror or the second mirror may include at least one reflector pair that includes a semiconductor material layer and an oxidized semiconductor material layer, and an oxidation trench axially extending into at least the second mirror.

In some implementations, a method may include growing, on a substrate layer, a set of epitaxial layers that includes a first mirror, a second mirror, and an active region between the first mirror and the second mirror. The method may include etching an oxidation trench in the set of epitaxial layers, the oxidation trench axially extending into the second mirror. The method may include oxidizing the second mirror to form at least one reflector pair of the second mirror that comprises a semiconductor material layer and an oxidized semiconductor material layer.

### BRIEF DESCRIPTION OF THE DRAWINGS

FIGS. 1A and 1B are diagrams illustrating a top view of an example emitter, and a cross-sectional view of the example emitter along the line X-X, respectively.

FIGS. 2A and 2B are diagrams illustrating a top-view of an example emitter device and a cross-sectional view of the example emitter device along the line Y-Y, respectively.

FIGS. 2C-2F are diagrams illustrating top views of an example emitter device.

FIG. 3 is a diagram illustrating a cross-sectional view of an example emitter device.

FIG. 4 is a flowchart of an example process relating to fabricating an emitter with an oxide-layer-based reflector pair.

### DETAILED DESCRIPTION

The following detailed description of example implementations refers to the accompanying drawings. The same reference numbers in different drawings may identify the same or similar elements.

A vertical cavity surface emitting laser (VCSEL) may be employed in various applications that use direct modulation, such as fiber optic communications. For a directly modulated VCSEL, enhancing differential gain, and minimizing mode volume, threshold current, and threshold current density, is desirable for maximizing modulation bandwidth.

A VCSEL may include an upper mirror and a lower mirror that define an optical cavity. The upper mirror and the lower mirror may each include sets of reflector pairs that are formed by epitaxial layers with varied aluminum compositions in aluminum gallium arsenide (AlGaAs), where the reflectivity of a reflector pair is defined by a difference in respective refractive indexes of the layers of the reflector pair. For example, a difference in refractive indexes of a high-aluminum composition AlGaAs layer (e.g., approximately a 3.0 refractive index) and a low-aluminum composition AlGaAs layer (e.g., approximately a 3.5 refractive index) of a reflector pair may be about 0.5. Thus, using such reflector pairs may increase the number of reflector pairs needed to obtain sufficient reflectivity for lasing, thereby increasing epitaxial thickness, mode volume in a longitudinal direction, and absorption loss.

In some implementations, an emitter device (e.g., a VCSEL device) may include a set of epitaxial layers that includes a first mirror, a second mirror, and an active region between the first mirror and the second mirror. In some implementations, at least one of the first mirror or the second mirror may include at least one reflector pair that includes a semiconductor material layer (e.g., AlGaAs) and an oxidized semiconductor material layer (e.g., oxidized AlGaAs). In some implementations, the set of epitaxial layers may include an oxidation trench that axially extends into the second mirror (e.g., if the second mirror is to include one or more such reflector pairs) or into the second mirror and the first mirror (e.g., if the first mirror is to include one or more such reflector pairs). The oxidation trench may facilitate oxidation of the oxidized semiconductor material layer in one or more reflector pairs.

In one example, a reflector pair may include a low-aluminum composition AlGaAs layer and a high-aluminum composition AlGaAs layer (e.g., Al0.98GaAs) that is oxidized (thereby converting the aluminum to aluminum oxide). The low-aluminum composition AlGaAs layer may have a refractive index that is approximately 3.5, as described above. The oxidized high-aluminum composition AlGaAs layer (e.g., which if not oxidized may have a refractive index that is approximately 3.0, as described above) may have a refractive index that is approximately 1.7. Accordingly, the oxidized high-aluminum composition AlGaAs layer increases the difference in refractive indexes of the layers of the reflector pair to about 1.8 (e.g., relative to a difference of about 0.5 if the high-aluminum composition AlGaAs layer is not oxidized, as described above).

Increasing the difference in refractive indexes of the layers of the reflector pair increases the reflectivity of the reflector pair. In this way, the number of reflector pairs that are needed in a mirror (e.g., needed for achieving a reflectivity sufficient to produce lasing) may be reduced, thereby reducing an epitaxial thickness (e.g., providing reduced form factor) and a mode volume. Moreover, reducing the number of reflector pairs and epitaxial thickness, as well as a lower absorption loss of oxidized semiconductor material layer relative to semiconductor material layer, may lower internal loss and reduce a laser threshold current density. The reduced laser threshold current density facilitates higher differential gain, and the reduced mode volume increases a confinement factor. In this way, the reflector pairs described herein improve laser modulation bandwidth by reducing laser threshold current density and mode volume.

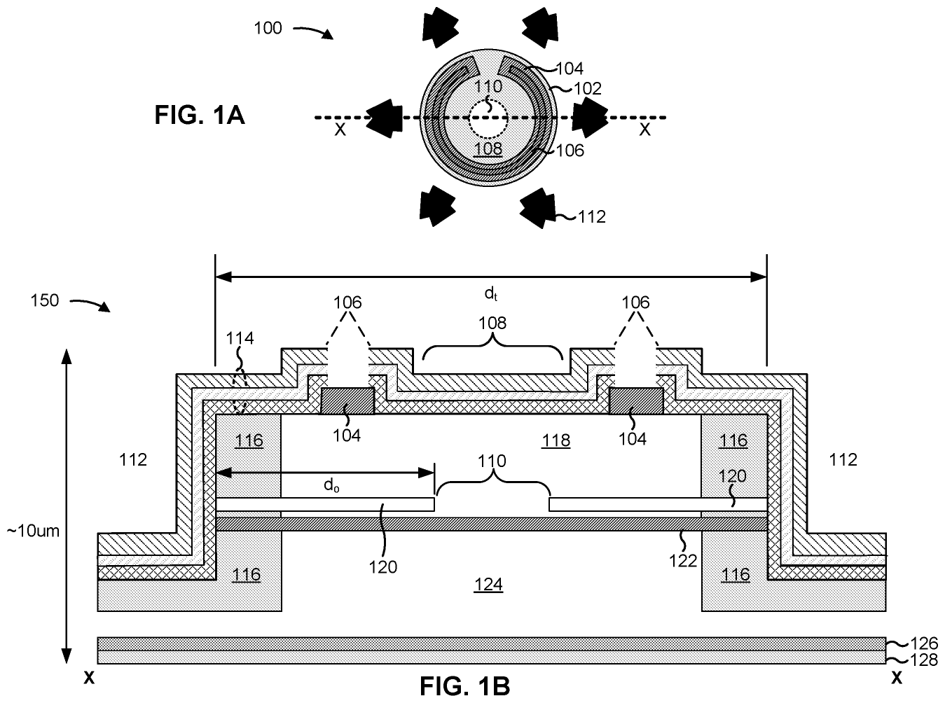

FIGS. 1A and 1B are diagrams illustrating a top view of an example emitter 100, and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g., a dielectric layer or a passivation layer) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxidation aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dₜ. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al₂O₃ layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. Current confinement aperture 110 may provide confinement of current injected to emitter 100 as well as confinement of optical energy of emitter 100. A size of current confinement aperture 110 may be greater than 2 μm in diameter, thereby supporting multiple modes in emitter 100. For example, a size of current confinement aperture 110 may range from approximately 4 μm to approximately 20 μm in diameter. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as d₀ in FIG. 1B) toward a center of emitter 100, thereby forming oxidation layer 120 and current confinement aperture 110. In some implementations, current confinement aperture 110 may include an oxidation aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO₂ layer, a Si₃N₄ layer, an Al₂O₃ layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

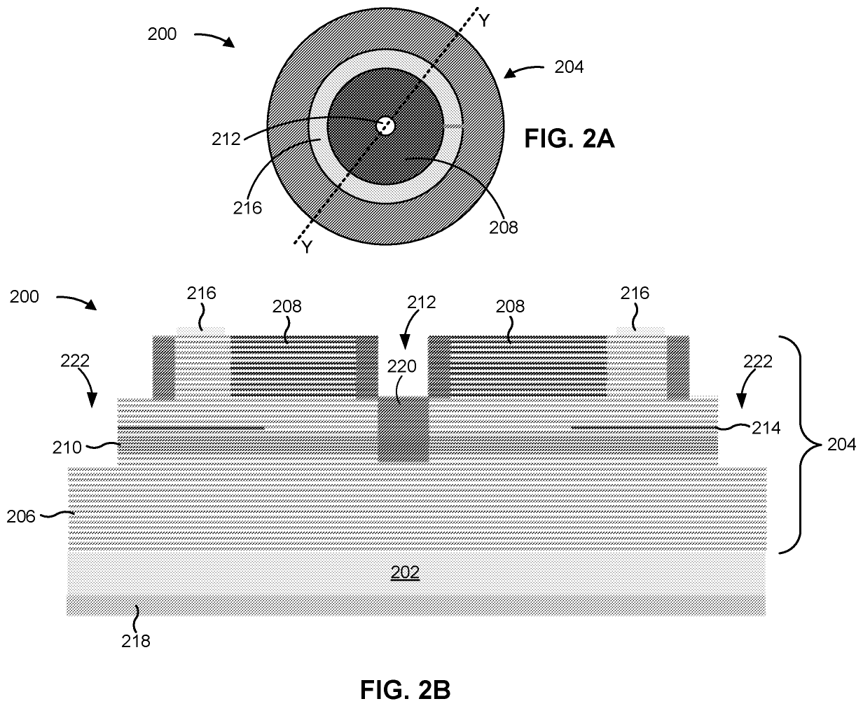

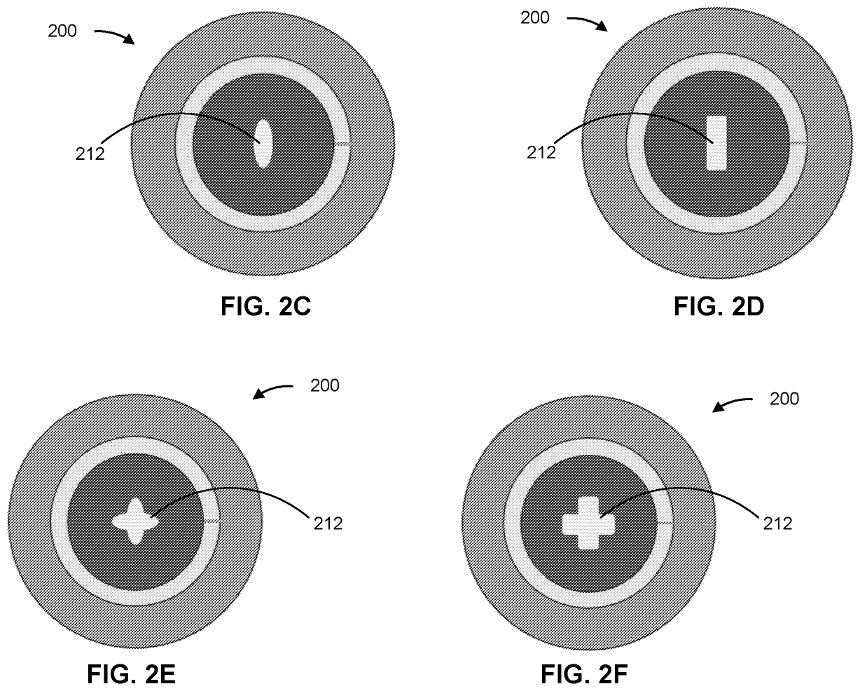

FIGS. 2A and 2B are diagrams illustrating a top view of an example emitter device 200 and a cross-sectional view of example emitter device 200 along the line Y-Y, respectively. The emitter device 200 may be a VCSEL device. As shown in FIGS. 2A and 2B, the emitter device 200 may include a substrate layer 202 and a set of epitaxial layers 204 disposed on (e.g., formed on) the substrate layer 202, as described in connection with FIGS. 1A and 1B. The set of epitaxial layers 204 may include a first mirror 206 (e.g., a first DBR), a second mirror 208 (e.g., a second DBR), and an active region 210 (e.g., a quantum well) between the first mirror 206 and the second mirror 208. The set of epitaxial layers 204 may include an oxidation trench 212 (e.g., etched down into the set of epitaxial layers 204) for oxidizing layers in reflector pairs of the first mirror 206 and/or the second mirror 208, as described herein. The set of epitaxial layers 204 may include an oxidation layer 214 with an oxidation aperture. The emitter device 200 may include an electrical contact layer 216 (e.g., an ohmic metal layer) electrically connected to the set of epitaxial layers 204, and another electrical contact layer 218 electrically connected to the substrate layer 202. That is, the electrical contact layer 216 may be a top contact of the emitter device 200, and the electrical contact layer 218 may be a bottom contact of the emitter device 200.

As shown in FIG. 2A, the second mirror 208 may surround the oxidation trench 212. For example, the oxidation trench 212 may extend axially into at least the second mirror 208. In some implementations, the oxidation trench 212 may be concentric with at least the second mirror 208. In some other implementations, the oxidation trench 212 may extend along an off-center axis of the second mirror 208. Thus, based on the position of the oxidation trench 212, the emitter device 200 may have a ring shape (e.g., a doughnut shape, an annular shape, etc.) as shown in FIG. 2A.

As shown in FIG. 2A, the oxidation trench 212 may have a cross-sectional shape that is a circle. In some implementations, the cross-sectional shape of the oxidation trench 212 may be a shape other than a circle (e.g., a cross, a rectangle, an octagon, or the like), as described in connection with FIGS. 2C-2F. The cross-sectional shape of the oxidation trench 212 may facilitate beam steering for the emitter device 200. Thus, the oxidation trench 212 may define an emitting region of the emitter device 200. As shown in FIG. 2A, the electrical contact layer 216 may include a slot to facilitate lithography.

As shown in FIG. 2B, the oxidation trench 212 may extend (e.g., partially or fully) into the second mirror 208, to thereby facilitate oxidation of reflector pair layers of the second mirror 208 (e.g., one or more reflector pairs of the second mirror 208 may be oxide-layer-based reflector pairs, as described herein). In some implementations, the oxidation trench 212 may not extend into the first mirror 206, such that reflector pair layers of the first mirror 206 are not oxidized. In some implementations, the oxidation trench 212 may extend (e.g., partially or fully) into the first mirror 206, to thereby facilitate oxidation of reflector pair layers of the first mirror 206 (e.g., one or more reflector pairs of the first mirror 206 may be oxide-layer-based reflector pairs, as described herein). This may also facilitate oxidation of reflector pair layers of the second mirror 208. However, in some implementations, the compositions of the reflector pair layers of the first mirror 206 and the compositions of the reflector pair layers of the second mirror 208 may be different (e.g., the reflector pair layers of the second mirror 208 may include lower-aluminum compositions than the reflector pair layers of the first mirror 206), such that the oxidation trench 212 facilitates oxidation of the reflector pair layers of the first mirror 206 without causing oxidation (e.g., without causing significant oxidation) of the reflector pair layers of the second mirror 208. In some implementations, an implant region 220 may surround the oxidation trench 212.

The first mirror 206 may include a set of reflector pairs (e.g., one or more reflector pairs) that define a reflectivity of the first mirror 206 and/or the second mirror 208 may include a set of reflector pairs (e.g., one or more reflector pairs) that define a reflectivity of the second mirror 208. For example, the first mirror 206 may be a DBR (e.g., a bottom DBR of the emitter device 200) and the second mirror 208 may be a DBR (e.g., a top DBR of the emitter device 200). At least one reflector pair of the first mirror 206 and/or the second mirror 208 may include an oxide-layer-based reflector pair. An oxide-layer-based reflector pair may include a semiconductor material layer and an oxidized semiconductor material layer. For example, the semiconductor material layer may include aluminum gallium arsenide, or the like, and the oxidized semiconductor material layer may include aluminum oxide gallium arsenide, or the like.

The semiconductor material layer may be non-oxidized. For example, although some oxidizing of the semiconductor material layer may occur, an extent of oxidation (e.g., a percentage of oxidation, an area of oxidation, or the like) of the semiconductor material layer is less than an extent of oxidation of the oxidized semiconductor material layer. This may be achieved when a composition of the semiconductor material layer is different from a composition (e.g., a starting composition prior to oxidation) of the oxidized semiconductor material layer. For example, an aluminum content of the oxidized semiconductor material layer may be higher than an aluminum content of the semiconductor material layer. In some implementations, a refractive index of the semiconductor material layer may be equal to or greater than 3.0, equal to or greater than 3.25, or equal to or greater than 3.5, and a refractive index of the oxidized semiconductor material layer may be equal to or less than 2.0, equal to or less than 1.85, or equal to or less than 1.7. In some implementations, a difference between a refractive index of the semiconductor material layer and a refractive index of the oxidized semiconductor layer is equal to or greater than 1, equal to or greater than 1.2, equal to or greater than 1.5, or equal to or greater than 1.8.

In some implementations, the first mirror 206 and/or the second mirror 208 may include at least one oxide-layer-based reflector pair and at least one reflector pair that does not include an oxidized layer (e.g., the at least one reflector pair may include a high-aluminum composition semiconductor material and a low-aluminum composition semiconductor material, as described herein). In some implementations, multiple reflector pairs of the first mirror 206 and/or of the second mirror 208 may be oxide-layer-based reflector pairs. For example, all of the reflector pairs of the first mirror 206 and/or of the second mirror 208 may be oxide-layer-based reflector pairs. Alternatively, the first mirror 206 and/or the second mirror 208 may include the multiple oxide-layer-based reflector pairs and one or more reflector pairs that do not include an oxidized layer. Here, the multiple oxide-layer-based reflector pairs may be in a continuous group, or the multiple oxide-layer-based reflector pairs may be interleaved with reflector pairs that do not include an oxidized layer.

The emitter device 200 may include one or more oxide-layer-based reflector pairs in addition to the oxidation layer 214. In other words, oxidized semiconductor material layers of the oxide-layer-based reflector pairs may be distinct from the oxidation layer 214. For example, the oxidation layer 214 may include an oxidation aperture for current confinement and/or for confinement of optical power, whereas the oxidized semiconductor material layers of the oxide-layer-based reflector pairs may not include apertures. Moreover, the oxidation layer 214 may be between the second mirror 208 and the active region 210. In addition to the oxidation trench 212, the emitter device 200 may include multiple trenches 222 for oxidizing the oxidation layer 214. For example, the trenches 222 may be etched at a lateral edge of the set of epitaxial layers 204 to expose the oxidation layer 214.

The electrical contact layer 216 may be disposed on the second mirror 208. As shown in FIG. 2B, oxidation of oxidized semiconductor material layers of the oxide-layer-based reflector pairs may extend short of an edge of the second mirror 208 (e.g., short of an edge of a structure that includes the second mirror 208). In this way, the oxidation of the oxidized semiconductor material layers provides (e.g., leaves) a path for electrical current, and the electrical contact layer 216 may be electrically connected to the path. Accordingly, electrical current, confined by the oxidation layer 214 as well as the implant region 220, may flow from the electrical contact layer 216 through the path and to the electrical contact layer 218.

In some implementations, the compositions of the oxidized semiconductor material layers of multiple reflector pairs (e.g., of the first mirror 206 or of the second mirror 208) may be different (e.g., along a growth direction of the set of epitaxial layers 204). For example, an aluminum content of an oxidized semiconductor material layer of a first reflector pair may be different from an aluminum content of an oxidized semiconductor material layer of a second reflector pair. In this way, respective oxidations of the oxidized semiconductor material layers of the multiple reflector pairs may be for different distances (e.g., different distances away from the oxidation trench 212).

By using oxide-layer-based reflector pair(s), as described herein, the emitter device 200 may achieve a reduced threshold current density and/or a reduced mode volume, thereby improving a laser modulation bandwidth of the emitter device 200. Moreover, the oxide-layer-based reflector pair(s) facilitate reduction of a thickness of the set of epitaxial layers 204 (e.g., fewer reflector pairs are needed to achieve a desired reflectivity). For example, fewer reflector pairs may be used in the emitter device 200 as the difference between refractive indexes of the semiconductor material layer and the oxidized semiconductor material layer of a reflector pair increases and/or if the oxidized semiconductor material layer is closer to the active region 210 (e.g., than the semiconductor material layer).

As indicated above, FIGS. 2A and 2B are provided as examples. Other examples may differ from what is described with regard to FIGS. 2A and 2B.

FIGS. 2C-2F are diagrams illustrating alternative top views of the example emitter device 200. As described above, the cross-sectional shape of the oxidation trench 212 may be a shape other than a circle. As shown in FIG. 2C, the cross-sectional shape of the oxidation trench 212 may be elliptical, or oval-shaped. As shown in FIG. 2D, the cross-sectional shape of the oxidation trench 212 may be rectangular. As shown in FIG. 2E, the cross-sectional shape of the oxidation trench 212 may be in the shape of orthogonally intersecting ellipses (e.g., a quatrefoil shape). As shown in FIG. 2F, the cross-sectional shape of the oxidation trench 212 may be in the shape of orthogonally intersecting rectangles (e.g., a cross shape). The cross-sectional shape of the oxidation trench 212 may be a shape other than those shown in FIGS. 2A and 2C-2F. The cross-sectional shape of the oxidation trench 212 may be used to control modes and/or polarization of the emitter device 200. For example, the cross-sectional shape of the oxidation trench 212 may be selected to provide particular mode control and/or polarization control for the emitter device 200.

As indicated above, FIGS. 2C-2F are provided as examples. Other examples may differ from what is described with regard to FIGS. 2C-2F.

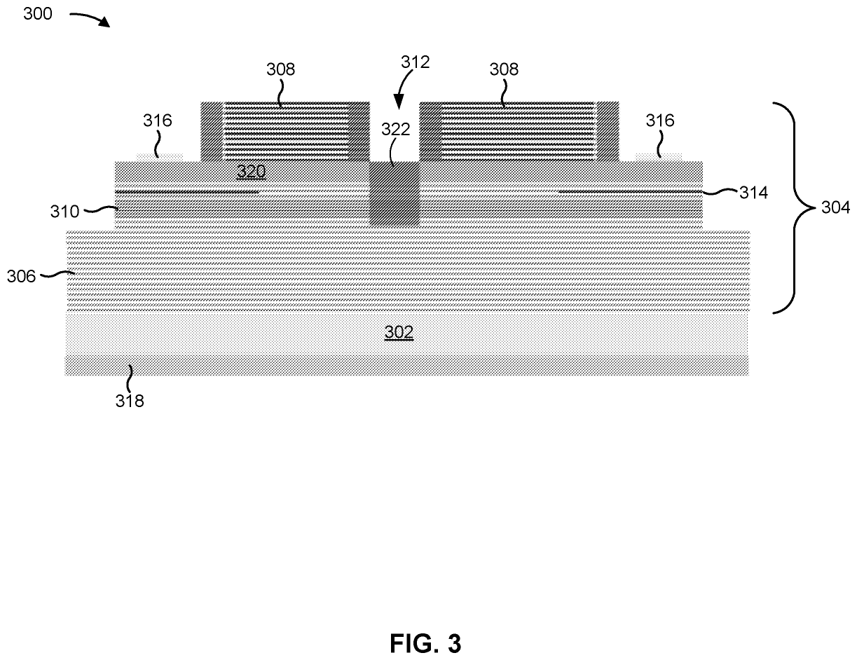

FIG. 3 is a diagram illustrating a cross-sectional view of an example emitter device 300. The emitter device 300 may be a VCSEL device. As shown in FIG. 3, the emitter device 300 may include a substrate 302 and a set of epitaxial layers 304 disposed on the substrate 302, in a similar manner as described in connection with FIGS. 2A-2B. For example, the set of epitaxial layers 304 may include a first mirror 306, a second mirror 308, an active region 310 (e.g., a quantum well) between the first mirror 306 and the second mirror 308, an oxidation trench 312, and an oxidation layer 314 with an oxidation aperture, in a similar manner as described in connection with FIGS. 2A-2B. In particular, the first mirror 306 and/or the second mirror 308 may include at least one oxide-layer-based reflector pair, in a similar manner as described in connection with FIGS. 2A-2B. Moreover, the emitter device 300 may include an electrical contact layer 316 (e.g., a top electrical contact layer) and an electrical contact layer 318 (e.g., a bottom electrical contact layer), in a similar manner as described in connection with FIGS. 2A-2B.

As shown in FIG. 3, the set of epitaxial layers 304 may include a buffer layer 320 (e.g., a contact buffer layer). The buffer layer 320 may include aluminum gallium arsenide (e.g., a low-aluminum composition aluminum gallium arsenide). The buffer layer 320 may be between the second mirror 308 and the active region 310. For example, the buffer layer 320 may be between the second mirror 308 and the oxidation layer 314. The second mirror 308 may be disposed on the buffer layer 320 such that a portion of the buffer layer 320 is exposed (e.g., by etching). The electrical contact layer 316 may be disposed on the portion of the buffer layer 320 that is exposed. By employing the buffer layer 320, and in contrast to the emitter device 200, oxidation of oxidized semiconductor material layers of oxide-layer-based reflector pairs may extend to an edge of the second mirror 308 (e.g., to an edge of a structure that includes the second mirror 308). Electrical current, confined by the oxidation layer 314 as well as an implant region 322, may flow from the electrical contact layer 316 to the electrical contact layer 318.

As indicated above, FIG. 3 is provided as an example. Other examples may differ from what is described with regard to FIG. 3.

As described herein, the emitter device 200 and/or the emitter device 300 may be a VCSEL device. The description herein may be applicable to various VCSEL architectures, such as an oxide-confined architecture, an implant-only architecture, a mesa-type architecture, or the like. Moreover, the description herein is applicable across different emission wavelengths (e.g., from 900 nanometers (nm) to 1550 nm) and/or across different material systems (e.g., a material system using a GaAs substrate, a material system using an InP substrate, or the like). Furthermore, the description herein is equally applicable to top-emitting devices and bottom-emitting devices. In some implementations, an array of emitters (e.g., a VCSEL array) may include one or multiple of the emitter device 200 and/or one or multiple of the emitter device 300. A quantity of emitters in the array and/or a shape of the array may be adjusted based on an application for which the array is intended. Moreover, a size of an emitter may be adjusted based on an application for which the emitter is intended.

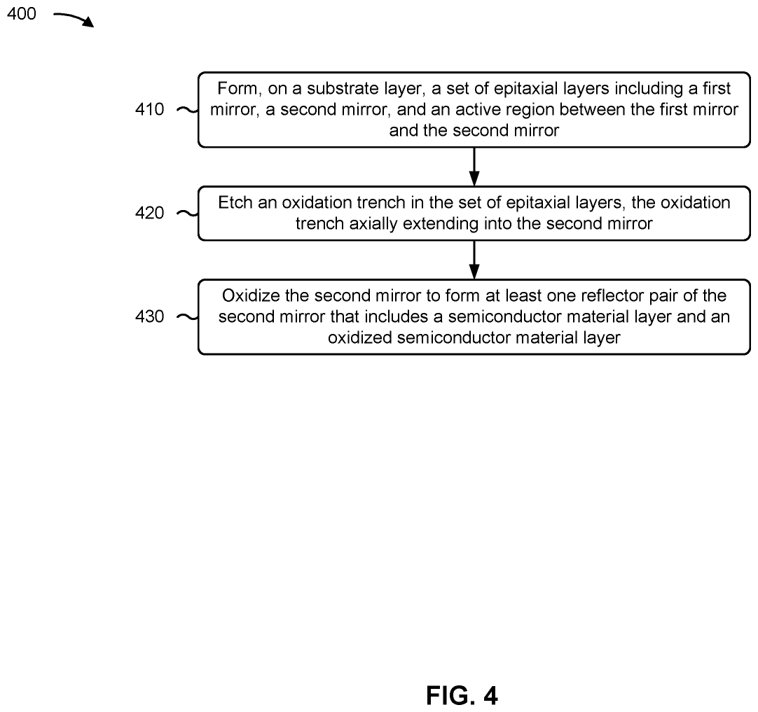

FIG. 4 is a flowchart of an example process 400 relating to fabricating an emitter with an oxide-layer-based reflector pair.

As shown in FIG. 4, process 400 may include forming, on a substrate layer, a set of epitaxial layers including a first mirror, a second mirror, and an active region between the first mirror and the second mirror (block 410). For example, the set of epitaxial layers may be formed as described herein. As further shown in FIG. 4, process 400 may include etching an oxidation trench in the set of epitaxial layers, the oxidation trench axially extending into the second mirror (block 420). For example, the oxidation trench may be positioned and shaped as described herein. As further shown in FIG. 4, process 400 may include oxidizing the second mirror to form at least one reflector pair of the second mirror that includes a semiconductor material layer and an oxidized semiconductor material layer (block 430). For example, the at least one reflector pair may be as described herein.

Process 400 may include additional implementations, such as any single implementation or any combination of implementations described below and/or in connection with one or more other processes described elsewhere herein.

In a first implementation, process 400 includes depositing an electrical contact layer on the set of epitaxial layers. In a second implementation, alone or in combination with the first implementation, process 400 includes etching a trench at a lateral edge of the set of epitaxial layers to expose an oxidation layer of the set of epitaxial layers, and oxidizing the oxidation layer to form an oxidation aperture. In a third implementation, alone or in combination with one or more of the first and second implementations, the semiconductor material layer includes aluminum gallium arsenide and the oxidized semiconductor material layer comprises aluminum oxide gallium arsenide.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical cavity surface emitting laser (VCSEL) device, comprising:
a substrate layer; and
a set of epitaxial layers, disposed on the substrate layer, comprising:
a first mirror and a second mirror,
wherein at least one of the first mirror or the second mirror comprises at least one reflector pair that comprises a semiconductor material layer and an oxidized semiconductor material layer;
an oxidation trench axially extending into at least the second mirror;
an active region between the first mirror and the second mirror; and
an oxidation layer with an oxidation aperture.

2. The VCSEL device of claim 1, wherein the semiconductor material layer comprises aluminum gallium arsenide and the oxidized semiconductor material layer comprises aluminum oxide gallium arsenide.

3. The VCSEL device of claim 2, wherein an aluminum content of the oxidized semiconductor material layer is higher than an aluminum content of the semiconductor material layer.

4. The VCSEL device of claim 1, wherein a difference between a refractive index of the semiconductor material layer and a refractive index of the oxidized semiconductor material layer is greater than 1.

5. The VCSEL device of claim 1, wherein the at least one reflector pair comprises multiple reflector pairs.

6. The VCSEL device of claim 1, further comprising:
an electrical contact layer disposed on the second mirror,
wherein oxidation of the oxidized semiconductor material layer extends short of an edge of the second mirror to provide a path for electrical current from the electrical contact layer.

7. The VCSEL device of claim 1, wherein the set of epitaxial layers further comprises:
a buffer layer,
wherein the second mirror is disposed on the buffer layer to expose a portion of the buffer layer, and
wherein the VCSEL device further comprises:
an electrical contact layer disposed on the portion of the buffer layer.

8. The VCSEL device of claim 1, wherein the oxidation trench defines an emitting region of the VCSEL device.

9. The VCSEL device of claim 1, wherein a cross-sectional shape of the oxidation trench is a shape other than a circle.

10. An emitter device, comprising:
a substrate layer; and
a set of epitaxial layers, disposed on the substrate layer, comprising:
a first mirror and a second mirror,
wherein at least one of the first mirror or the second mirror comprises at least one reflector pair that comprises a semiconductor material layer and an
oxidized semiconductor material layer; and
an oxidation trench axially extending into at least the second mirror.

11. The emitter device of claim 10, wherein the at least one reflector pair is one or more first reflector pairs of the first mirror and one or more second reflector pairs of the second mirror.

12. The emitter device of claim 10, wherein the at least one reflector pair is one or more reflector pairs of the second mirror, and
wherein the oxidation trench axially extends into the second mirror.

13. The emitter device of claim 10, wherein the at least one reflector pair is one or more reflector pairs of the first mirror, and
wherein the oxidation trench axially extends into the first mirror.

14. The emitter device of claim 10, wherein the oxidation trench is concentric with at least the second mirror.

15. The emitter device of claim 10, wherein the at least one reflector pair comprises multiple reflector pairs.

16. The emitter device of claim 10, wherein the set of epitaxial layers further comprises an oxidation layer with an oxidation aperture.

17. A method, comprising:
forming, on a substrate layer, a set of epitaxial layers comprising a first mirror, a second mirror, and an active region between the first mirror and the second mirror;
etching an oxidation trench in the set of epitaxial layers,
the oxidation trench axially extending into the second mirror; and
oxidizing the second mirror to form at least one reflector pair of the second mirror that comprises a semiconductor material layer and an oxidized semiconductor material layer.

18. The method of claim 17, further comprising:
depositing an electrical contact layer on the set of epitaxial layers.

19. The method of claim 17, further comprising:
etching a trench at a lateral edge of the set of epitaxial layers to expose an oxidation layer of the set of epitaxial layers; and
oxidizing the oxidation layer to form an oxidation aperture.

20. The method of claim 17, wherein the semiconductor material layer comprises aluminum gallium arsenide and the oxidized semiconductor material layer comprises aluminum oxide gallium arsenide.
